(19) United States
(12) Patent Application Publication
(10) Pub. No.: US 2024/0357767 A1
(43) Pub. Date: Oct. 24, 2024

(54) LIQUID COOLING CABINET EQUIPMENT AND CONTROL METHOD THEREOF

(71) Applicant: LITE-ON Technology Corporation, Taipei City (TW)

(72) Inventors: Kun-Sung CHANG, Taipei City (TW); KimChye ONG, Singapore (SG); Tzu-Cheng FANG, Taipei City (TW); Yung-Chang CHIU, Taipei City (TW)

(73) Assignee: LITE-ON Technology Corporation, Taipei City (TW)

(21) Appl. No.: 18/336,910

(22) Filed: Jun. 16, 2023

(30) Foreign Application Priority Data
Apr. 21, 2023 (TW) 112114988

(51) Int. Cl. H05K 7/20

(52) U.S. Cl. CPC H05K 7/20281; H05K 7/20263; H05K 7/20272

(57) ABSTRACT

Disclosed is a liquid cooling cabinet equipment including a load device, a power supply device for supplying power to the load device and a liquid cooling system, which includes a liquid storage tank, a primary fluid loop pipeline, a secondary fluid loop pipeline connected to the liquid storage tank, a heat exchanger, a circulation motor, a power sensor, and a control device. The circulation motor drives a coolant in the liquid storage tank to circulate in the secondary fluid loop pipeline. After exchanging heat with the load device, the coolant in the secondary fluid loop pipeline exchanges heat with another coolant in the primary fluid loop pipeline through the heat exchanger. The control device controls a rotation speed of the circulation motor based on an output power of the power supply device sensed by the power sensor to adjust a flow of the coolant in the secondary fluid loop pipeline.

### CROSS REFERENCE TO RELATED PRESENT DISCLOSURE

This application claims the priority benefit of Taiwan Patent Application Serial Number 112114988, filed on Apr. 21, 2023, the full disclosure of which is incorporated herein by reference.

### BACKGROUND

### Technical Field

The present disclosure relates to a liquid cooling cabinet equipment and a control method thereof, and in particular, to a liquid cooling cabinet equipment and a control method thereof based on power load information.

### Related Art

When a load device is in operation, a large amount of heat is generated. If the load device overheats, the operation speed may be slowed down or the load device may crash. Therefore, the load device has a certain degree of heat dissipation performance requirement. Conventional load devices usually use airflow to dissipate heat. However, when the performance of the load device is improved, the original air-cooled heat dissipation method does not meet the requirement.

In view of this, based on the fact that the heat conductivity of the liquid medium is much higher than that of the traditional air medium, relevant companies have proposed a liquid cooling system using a liquid medium for heat exchange. However, the liquid medium is slower in control response, so that when the thermal load of the load device suddenly increases, the liquid cooling system cannot quickly reach the set thermal equilibrium, resulting in overheating of the load device, which affects the life of each component in the load device. In severe cases, the overheating protection mechanism of the load device is triggered to shut down the load device, causing serious losses to the system where the load device is applied.

### SUMMARY

The embodiments of the present disclosure provide a liquid cooling cabinet equipment and a control method thereof, which can effectively solve the problem that the existing liquid cooling system cannot quickly reach the set thermal equilibrium when the thermal load of the load device suddenly increases due to the slow control response of the liquid medium.

The present disclosure provides a liquid cooling cabinet equipment, which includes a load device, a power supply device, and a liquid cooling system. The liquid cooling system includes a liquid storage tank, a primary fluid loop pipeline, a secondary fluid loop pipeline, a heat exchanger, a circulation motor, a power sensor, and a control device. The power supply device is configured to supply power to the load device. The primary fluid loop pipeline is connected to an external cooling device. The secondary fluid loop pipeline communicates with the liquid storage tank and is in thermal contact with the load device. A primary side of the heat exchanger communicates with the primary fluid loop pipeline, and a secondary side of the heat exchanger communicates with the secondary fluid loop pipeline. The circulation motor is configured to drive a coolant in the liquid storage tank to circulate in the secondary fluid loop pipeline, wherein after exchanging heat with the load device, the coolant in the secondary fluid loop pipeline exchanges heat with another coolant in the primary fluid loop pipeline through the heat exchanger. The power sensor is configured to sense an output power provided by the power supply device to the load device. The control device is connected to the circulation motor and is configured to receive power load information from the power sensor, and control a rotation speed of the circulation motor based on the power load information to adjust a flow of the coolant in the secondary fluid loop pipeline, wherein the power load information comprises the output power.

The present disclosure further provides a control method of a liquid cooling cabinet equipment, which is applied to the liquid cooling cabinet equipment. The liquid cooling cabinet equipment includes a load device, a power supply device for supplying power to the load device, a liquid storage tank, a primary fluid loop pipeline connected to an external cooling device, a secondary fluid loop pipeline communicating with the liquid storage tank and in thermal contact with the load device, a heat exchanger, and a circulation motor. The control method of the liquid cooling cabinet equipment includes the following steps: controlling the circulation motor to drive a coolant in the liquid storage tank to circulate in the secondary fluid loop pipeline, so that after the coolant in the secondary fluid loop pipeline exchanging heat with the load device, exchanging heat with another coolant in the primary fluid loop pipeline through the heat exchanger; sensing an output power provided by the power supply device to the load device, and outputting power load information, the power load information comprising the output power; and controlling a rotation speed of the circulation motor based on the power load information to adjust a flow of the coolant flowing in the secondary fluid loop pipeline.

In the embodiments of the present disclosure, the liquid cooling cabinet equipment and the control method thereof can predict the thermal load change of the load device in advance through the output power provided by the power supply device to the load device (i.e., the sensing result of the power sensor), and control the rotation speed of the circulation motor, to adjust the flow of the coolant flowing in the secondary fluid loop pipeline. Therefore, the thermal load is precooled, and the problem that the existing liquid cooling system cannot quickly reach the set thermal equilibrium when the thermal load of the load device suddenly increases due to the slow control response of the liquid medium can be alleviated.

### BRIEF DESCRIPTION OF THE DRAWINGS

Accompanying drawings described herein are intended to provide a further understanding of the present disclosure and form a part of the present disclosure, and exemplary embodiments of the present disclosure and descriptions thereof are intended to explain the present disclosure but are not intended to unduly limit the present disclosure. In the drawings:

FIG. 1 is a schematic architecture diagram of a liquid cooling cabinet equipment according to an embodiment of the present disclosure;

FIG. 2 is a schematic architecture diagram of a liquid cooling cabinet equipment according to another embodiment of the present disclosure;

FIG. 3 is a schematic architecture diagram of a liquid cooling cabinet equipment according to still another embodiment of the present disclosure;

FIG. 4 is a schematic architecture diagram of a liquid cooling cabinet equipment according to yet another embodiment of the present disclosure; and

FIG. 5 is a flow chart of a control method of a liquid cooling cabinet equipment according to an embodiment of the present disclosure.

### DETAILED DESCRIPTION OF THE EMBODIMENTS

The embodiments of the present disclosure will be described below in conjunction with the relevant drawings. In the figures, the same reference numbers refer to the same or similar components or method flows.

It must be understood that the words “including”, “comprising” and the like used in this specification are used to indicate the existence of specific technical features, values, method steps, work processes, elements and/or components. However, it does not exclude that more technical features, values, method steps, work processes, elements, components, or any combination of the above can be added.

It must be understood that when an element is described as being “connected” or “coupled” to another element, it may be directly connected or coupled to another element, and intermediate elements therebetween may be present. In contrast, when an element is described as being “directly connected” or “directly coupled” to another element, there is no intervening element therebetween.

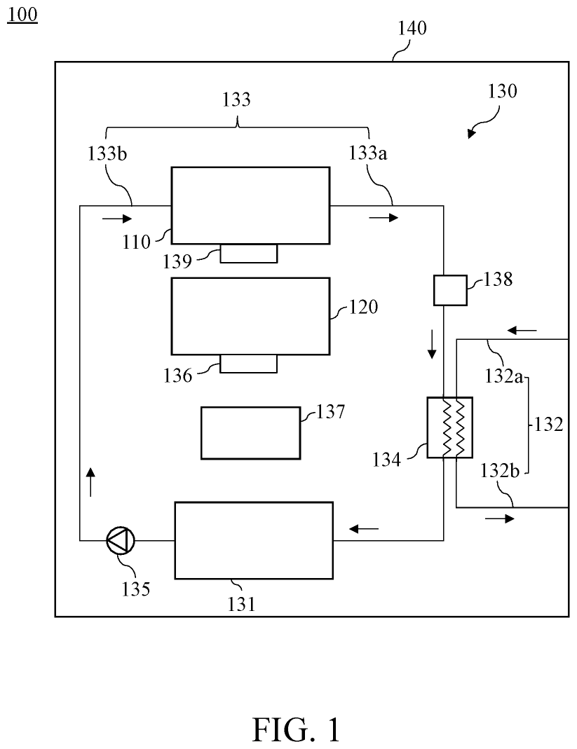

In addition, in order to avoid the drawings being too complicated, any electrical connection is omitted in the schematic architecture diagrams of FIG. 1 to FIG. 4, and the electrical connection relationship is only described and illustrated in each embodiment.

Please refer to FIG. 1, which is a schematic architecture diagram of a liquid cooling cabinet equipment according to an embodiment of the present disclosure. As shown in FIG. 1, in this embodiment, a liquid cooling cabinet equipment 100 comprises a load device 110, a power supply device 120, and a liquid cooling system 130, and the liquid cooling system 130 comprises a liquid storage tank 131, a primary fluid loop pipeline 132, a secondary fluid loop pipeline 133, a heat exchanger 134, a circulation motor 135, a power sensor 136 and a control device 137. The power supply device 120 is configured to supply power to the load device 110. The primary fluid loop pipeline 132 is connected to an external cooling device (not shown). The secondary fluid loop pipeline 133 communicates with the liquid storage tank 131 and is in thermal contact with the load device 110. A primary side of the heat exchanger 134 communicates with the primary fluid loop pipeline 132, and a secondary side of the heat exchanger 134 communicates with the secondary fluid loop pipeline 133. The circulation motor 135 is configured to drive a coolant in the liquid storage tank 131 to circulate in the secondary fluid loop pipeline 133, wherein after exchanging heat with the load device 110, the coolant in the secondary fluid loop pipeline 133 exchanges heat with another coolant in the primary fluid loop pipeline 132 through the heat exchanger 134. The power sensor 136 is configured to sense an output power provided by the power supply device 120 to the load device 110. The control device 137 is connected to the circulation motor 135 and is configured to receive power load information from the power sensor 136, and control a rotation speed of the circulation motor 135 based on the power load information to adjust a flow of the coolant flowing in the secondary fluid loop pipeline 133, wherein the power load information comprises the output power provided by the power supply device 120 to the load device 110.

In this embodiment, the load device 110 comprises, but not limited to, electronic components or electronic devices that generate heat when powered by the power supply device 120 for operation. In one example, the load device 110 may be a server, and when the power supply device 120 supplies power to the load device 110 to operate, the electronic component or electronic device that generates heat may be a processor or a printed circuit board assembly of the server.

In this embodiment, the liquid cooling system 130 is a closed cooling system, which can isolate against the contamination of impurities in the external environment, prevent dirt from entering the secondary fluid loop pipeline 133, and keep the coolant in the secondary fluid loop pipeline 133 always clean to effectively maintain a stable cooling temperature.

Specifically, the heat exchanger 134 can be but not limited to a plate heat exchanger, the primary fluid loop pipeline 132 can comprise a first input pipe 132a and a first output pipe 132b, and the external cooling device can comprise a cooling tower and a circulation pump. The external cooling device can communicate with the input port of the primary side of the heat exchanger 134 through the first input pipe 132a, and the external cooling device can communicate with the output port of the primary side of the heat exchanger 134 through the first output pipe 132b, so that the external cooling device, the primary fluid loop pipeline 132 and the primary side of the heat exchanger 134 form an external cooling loop. The circulation pump drives the circulation of the coolant in the primary fluid loop pipeline 132, and the coolant in the primary fluid loop pipeline 132 can be water, alcohol, or other suitable liquids. The secondary fluid loop pipeline 133 communicates with the liquid storage tank 131 and is in thermal contact with the load device 110, and the secondary fluid loop pipeline 133 can comprise a second input pipe 133a and a second output pipe 133b, wherein the second input pipe 133a communicates with the input port of the secondary side of the heat exchanger 134, the second output pipe 133b communicates with the output port of the secondary side of the heat exchanger 134, and the circulation motor 135 is disposed on the second output pipe 133b, so that the liquid storage tank 131, the secondary fluid loop pipeline 133, the circulation motor 135 and the secondary side of the heat exchanger 134 can form a closed internal cooling loop, and the circulation motor 135 drives the coolant in the liquid storage tank 131 to circulate in the secondary fluid loop pipeline 133. The coolant in the secondary fluid loop pipeline 133 can be water, alcohol, or other suitable liquids. The coolant in the secondary fluid loop pipeline 133 and the coolant in the primary fluid loop pipeline 132 may be the same or different.

Therefore, the liquid cooling system 130 can exchange heat with the load device 110 through the coolant in the secondary fluid loop pipeline 133, and the coolant in the external cooling loop exchanges heat with the coolant in the closed internal cooling loop in the heat exchanger 134, so that the thermal load of the load device 110 maintains a certain temperature. Since the performance of the load device 110 is improved, the output power provided by the power supply device 120 to the load device 110 is increased. Therefore, the liquid cooling cabinet equipment 100 can sense the output power provided by the power supply device 120 to the load device 110 through the power sensor 136, predict the change of the thermal load of the load device 110 in advance, and control the rotation speed of the circulation motor 135 to adjust the flow of the coolant flowing in the secondary fluid loop pipeline 133, thereby precooling the temperature of the thermal load.

In one embodiment, the power sensor 136 can transmit the power load information to the control device 137 through a wired transmission interface and/or a wireless transmission interface, wherein the wired transmission interface can be but not limited to a universal serial bus (USB) interface, a USB Type-C interface or an inter-integrated circuit bus (I2C Bus) interface, and the wireless transmission interface can be but not limited to Bluetooth, WiFi or a near field communication (NFC) interface.

In one embodiment, the power sensor 136 can be configured to obtain the output power provided by the power supply device 120 to the load device 110 based on a supply voltage and/or a supply current provided by the power supply device 120 to the load device 110.

In one embodiment, the power sensor 136 can be integrated into the power supply device 120.

In one embodiment, the control device 137 can be further configured to control the rotation speed of the circulation motor 135 based on the power load information and a look-up table to adjust the flow of the coolant flowing in the secondary fluid loop pipeline 133, wherein the lookup table may comprise the output power of different power supply devices 120 and the rotation speed values of the circulation motor 135 corresponding thereto. Therefore, the control device 137 can search the corresponding rotation speed value of the circulation motor 135 in the look-up table based on the output power provided by the power supply device 120 to the load device 110, and output a corresponding control signal to the circulation motor 135, so that the circulation motor 135 can operate according to the searched rotation speed value.

In one embodiment, the control device 137 can be further configured to control the rotation speed of the circulation motor 135 based on the power load information, and a rotation speed upper limit value and a rotation speed lower limit value of the circulation motor 135. Specifically, the control device 137 performs calculation based on the output power provided by the power supply device 120 to the load device 110 with a first preset formula to obtain the corresponding rotation speed value of the circulating motor 135, wherein the first preset formula can be adjusted according to actual needs. If the calculated rotation speed value is greater than the rotation speed upper limit value, the control device 137 outputs the corresponding control signal to the circulating motor 135 based on the rotation speed upper limit value, so that the circulating motor 135 operates according to the rotation speed upper limit value. If the calculated rotation speed value is less than the rotation speed lower limit value, the control device 137 outputs the corresponding control signal based on the rotation speed lower limit value to the circulating motor 135, so that the circulating motor 135 operates according to the rotation speed lower limit value. If the calculated rotation speed value is equal to or greater than the rotation speed lower limit value, or is equal to or less than the rotation speed upper limit value, the control device 137 outputs the corresponding control signal based on the calculated rotation speed value to the circulation motor 135, so that the circulation motor 135 operates according to the calculated rotation speed value.

In one embodiment, the power sensor 136 can be configured to periodically transmit the power load information to the control device 137, and the control device 137 is further configured to determine whether a variation of the output power provided by the power supply device 120 to the load device 110 is greater than a threshold, wherein the threshold can be adjusted according to actual needs. When the control device 137 determines that the variation of the output power is greater than the threshold, the control device 137 performs calculation based on the variation of the output power with a second preset formula to obtain a flow compensation value, and outputs a corresponding control signal to the circulation motor 135 based on the flow compensation value to control the rotation speed of the circulation motor 135. The second preset formula can be adjusted according to actual needs. Therefore, by periodically transmitting the power load information through the power sensor 136, and the design of the threshold, it can avoid the problem of damage to the circulation motor 135 caused by excessive control of the circulation motor 135 due to factors such as sensing errors of the output power.

In one embodiment, the liquid cooling cabinet equipment 100 may further comprise a cabinet body 140, and the load device 110, the power supply device 120 and the liquid cooling system 130 are integrated into an interior of the cabinet body 140.

In one embodiment, the cabinet 140 may comprise a load cabinet and a power supply cabinet, the load device 110 is detachably installed in the load cabinet, and the power supply device 120 is detachably installed in the power supply cabinet.

In one embodiment, the liquid cooling system 130 may further comprise a liquid temperature sensor 138, the liquid temperature sensor 138 may be configured to sense the temperature of the coolant flowing into the heat exchanger 134 in the secondary fluid loop pipeline 133, to output liquid temperature information to the control device 137, so that the control device 137 controls the rotation speed of the circulation motor 135 based on the power load information and the liquid temperature information. Therefore, when the power sensor 136 is damaged, the liquid cooling system 130 can also control the rotation speed of the circulation motor 135 through the sensing result of the liquid temperature sensor 138 to maintain the normal operation of the liquid cooling system 130.

In one embodiment, the liquid cooling system 130 may further comprise a load temperature sensor 139, the load temperature sensor 139 is configured to sense the temperature of the load device 110 to output load temperature information to the control device 137, so that the control device 137 controls the rotation speed of the circulation motor 135 based on the power load information and the load temperature information. Therefore, when the power sensor 136 is damaged, the liquid cooling system 130 can also control the rotation speed of the circulation motor 135 through the sensing result of the load temperature sensor 139 to maintain the normal operation of the liquid cooling system 130.

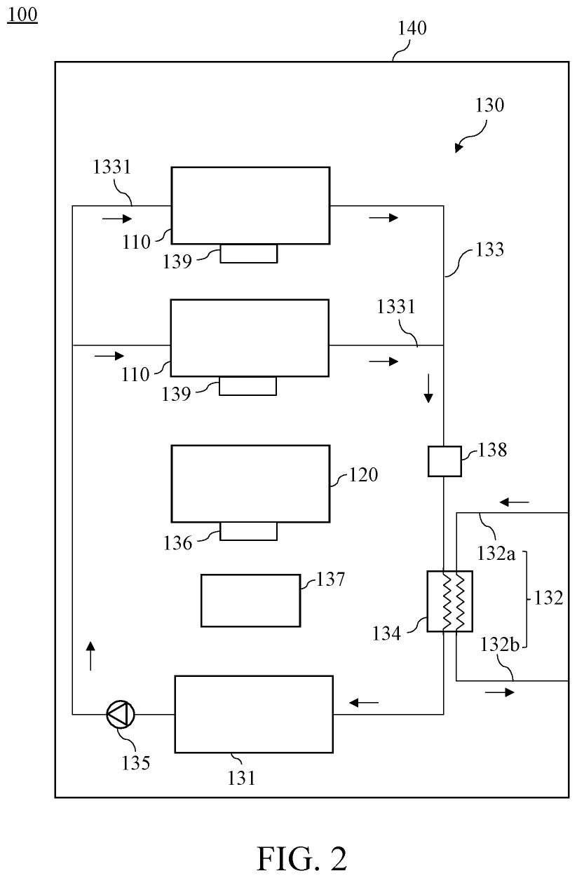

Please refer to FIG. 2, which is a schematic architecture diagram of a liquid cooling cabinet equipment according to another embodiment of the present disclosure. As shown in FIG. 2, in this embodiment, the number of load devices 110 is plural, and the load devices 110 are arranged in parallel through the secondary fluid loop pipeline 133, and the power supply device 120 supplies power to the load devices 110. The power sensor 136 is further configured to sense a total output power provided by the power supply device 120 to the load devices 110, and the power load information comprises the total output power provided by the power supply device 120 to the load devices 110. The secondary fluid loop pipeline 133 comprises a plurality of sub-pipelines 1331 arranged in parallel, and the plurality of sub-pipelines 1331 are in one-to-one thermal contact with the load devices 110, so that the load devices 110 are arranged in parallel through the secondary fluid loop pipeline 133. The flow of the coolant in each sub-pipeline 1331 can be the same.

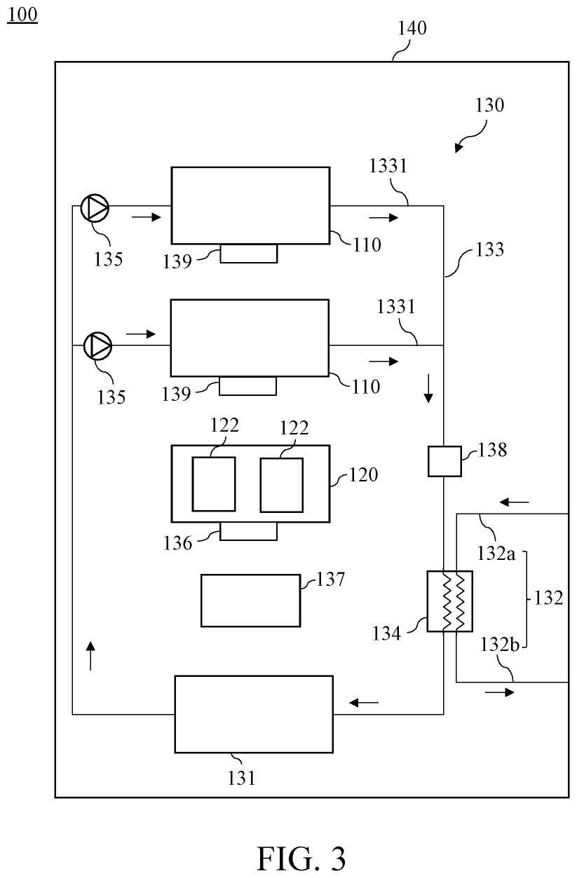

Please refer to FIG. 3, which is a schematic architecture diagram of a liquid cooling cabinet equipment according to still another embodiment of the present disclosure. As shown in FIG. 3, in this embodiment, the number of load devices 110 is plural, the power supply device 120 may comprise a plurality of power supply units 122, and the number of circulating motors 135 is plural. The plurality of power supply units 122, the circulation motors 135, and the load devices 110 are arranged in one-to-one correspondence, each power supply unit 122 is configured to supply power to the corresponding load devices 110, and each circulation motor 135 is configured to drive the flow of the coolant for heat exchange with the corresponding load device 110 (that is, each circulation motor 135 is configured to drive the flow of the coolant in the sub-pipeline 1331 in thermal contact with the corresponding load device 110).

In one embodiment, the power sensor 136 can be further configured to sense an output power of each power supply unit 122 that supplies power to the corresponding load device 110, and the power load information comprises the output power of each power supply unit 122 that supplies power to the corresponding load device 110. The control device 137 controls the rotation speed of each circulating motor 135 based on the power load information to adjust the flow of the coolant flowing through the corresponding load device 110 (that is, each circulating motor 135 is configured to drive the flow of the coolant in the sub-pipeline 1331 in thermal contact with the corresponding load device 110).

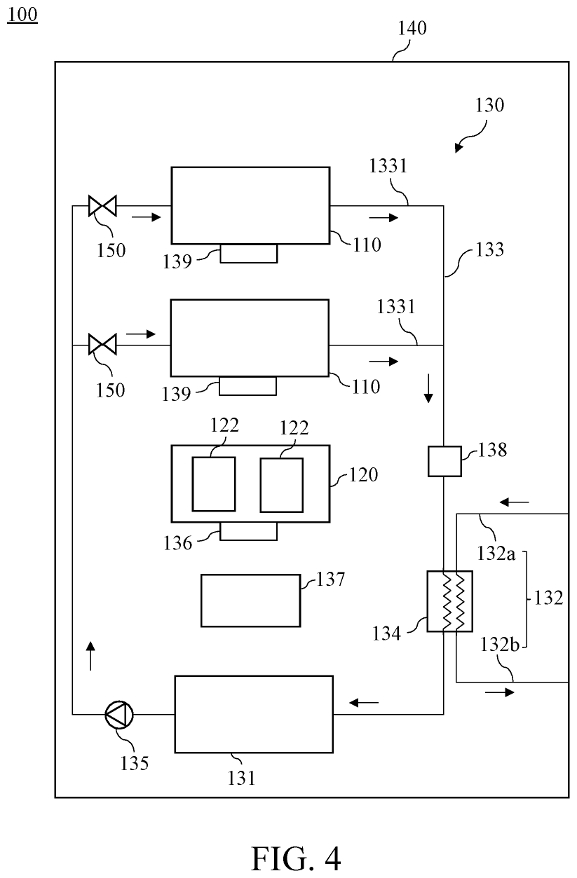

Please refer to FIG. 4, which is a schematic architecture diagram of a liquid cooling cabinet equipment according to yet another embodiment of the present disclosure. As shown in FIG. 4, in this embodiment, the liquid cooling system 130 may further comprise a plurality of flow control valves 150, the number of load devices 110 is plural, and the power supply device 120 comprises a plurality of power supply units 122. The plurality of power supply units 122, the flow control valves 150, and the load devices 110 are arranged in one-to-one correspondence, and the power sensor 136 can be further configured to sense an output power provided by each power supply unit 122 to the corresponding load device 110. The power load information comprises the output power provided by each power supply unit 122 to the corresponding load device 110 and the total output power provided by the power supply device 120 to the load devices 110. The control device 137 can be further configured to control each flow control valve 150 and the circulation motor 135 based on the power load information to adjust the flow of the coolant flowing through each corresponding load device 110. Specifically, the control device 137 controls the rotation speed of the circulation motor 135 based on the total output power provided by the power supply device 120 to the load devices 110, regulates the flow of the coolant in the overall secondary fluid loop pipeline 133, and based on the situation of different load devices 110, controls each flow control valve 150 according to the output power provided by each power supply unit 122 to the corresponding load device 110 to regulate the flow of the coolant in each sub-pipeline 1331.

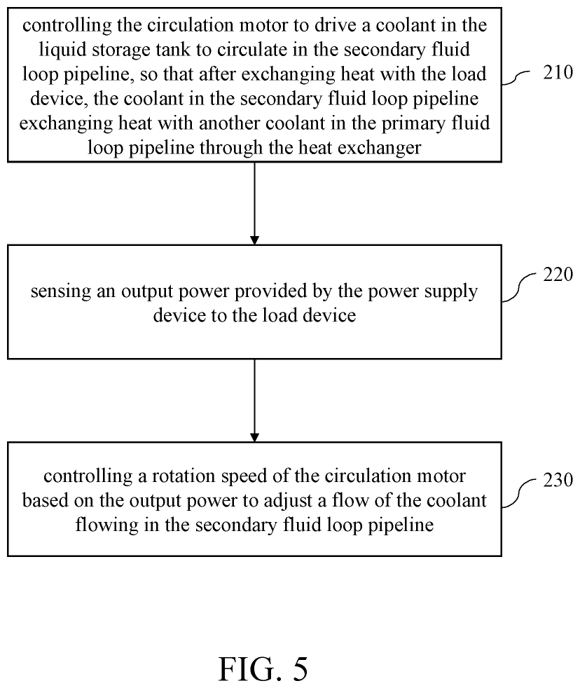

Please refer to FIG. 5, which is a flow chart of a control method of a liquid cooling cabinet equipment according to an embodiment of the present disclosure. As shown in FIG. 5, a control method of a liquid cooling cabinet equipment can be applied to the liquid cooling cabinet equipment 100 in FIG. 1, and the control method of the liquid cooling cabinet equipment comprises the following steps: controlling the circulation motor to drive a coolant in the liquid storage tank to circulate in the secondary fluid loop pipeline, so that after exchanging heat with the load device, the coolant in the secondary fluid loop pipeline exchanging heat with another coolant in the primary fluid loop pipeline through the heat exchanger (step 210); sensing an output power provided by the power supply device to the load device (step 220); and controlling a rotation speed of the circulation motor based on the output power to adjust a flow of the coolant flowing in the secondary fluid loop pipeline (step 230). The detailed description has been explained in the above paragraphs, and is not repeated here.

In one embodiment, step 230 may comprise: controlling the rotation speed of the circulation motor based on the output power and a look-up table. The detailed description has been explained in the above paragraphs, and is not repeated here.

In one embodiment, step 230 may comprise: controlling the rotation speed of the circulation motor based on the output power and a rotation speed upper limit value and a rotation speed lower limit value of the circulation motor. The detailed description has been explained in the above paragraphs, and is not repeated here.

In one embodiment, step 220 may comprise: periodically sensing the output power, and step 230 may comprise: determining whether a variation of the output power is greater than a threshold; and when it is determined that the variation of the output power is greater than the threshold, performing calculation based on the variation of the output power to obtain a flow compensation value, and controlling the rotation speed of the circulation motor based on the flow compensation value. The detailed description has been explained in the above paragraphs, and is not repeated here.

In one embodiment, the number of load devices is plural, the load devices are arranged in parallel through the secondary fluid loop pipeline, and the power supply device supplies power to the load devices as shown in the liquid cooling cabinet equipment 100 of FIG. 2, so that step 220 may comprise: sensing a total output power provided by the power supply device to the load devices, and outputting the power load information, the power load information comprising the total output power, and step 230 may comprise: controlling the rotation speed of the circulation motor based on the total output power to adjust the flow of the coolant flowing in the secondary fluid loop pipeline. The detailed description has been explained in the above paragraphs, and is not repeated here.

In one embodiment, the number of circulating motors is plural, the number of load devices is plural, the load devices are arranged in parallel through the secondary fluid loop pipeline, and the power supply device comprises a plurality of power supply units. The plurality of power supply units, the circulation motors and the load devices are arranged in one-to-one correspondence as shown in the liquid cooling cabinet equipment 100 in FIG. 3, so that step 220 may comprise: sensing an output power provided by each power supply unit to the corresponding load device, and outputting the power load information, the power load information comprising the output power provided by each power supply unit to the corresponding load device, and step 230 may comprise: controlling a rotation speed of each circulation motor based on the output power provided by each power supply unit to the corresponding load device to adjust a flow of the coolant flowing through the corresponding load device. The detailed description has been explained in the above paragraphs, and is not repeated here.

In one embodiment, the number of load devices is plural, and the load devices are arranged in parallel through the secondary fluid loop pipeline, the power supply device comprises a plurality of power supply units, and the liquid cooling system can further comprise a plurality of flow control valves. The plurality of power supply units, the plurality of flow control valves and the load devices are arranged in one-to-one correspondence as shown in the liquid cooling cabinet equipment 100 in FIG. 4, so that step 220 may comprise: sensing an output power provided by each power supply unit to the corresponding load device and a total output power provided by the power supply device to the load devices, and outputting the power load information, the power load information comprising the output power provided by each power supply unit to the corresponding load device and the total output power provided by the power supply device to the load devices, and step 230 may comprise: controlling each flow control valve and the circulation motor based on the power load information to adjust the flow of the coolant flowing through the corresponding load device. The detailed description has been explained in the above paragraphs, and is not repeated here.

In one embodiment, the control method of the liquid cooling cabinet equipment may further comprise: sensing a temperature of the coolant flowing into the heat exchanger in the secondary fluid loop pipeline to output liquid temperature information, so that step 230 may comprise: controlling the rotation speed of the circulation motor based on the power load information and the liquid temperature information. The detailed description has been explained in the above paragraphs, and is not repeated here.

In one embodiment, the control method of the liquid cooling cabinet equipment may further comprise: sensing a temperature of the load device to output load temperature information, so that step 230 may comprise: controlling the rotation speed of the circulation motor based on the power load information and the load temperature information. The detailed description has been explained in the above paragraphs, and is not repeated here.

To sum up, in the embodiments of the present disclosure, the liquid cooling cabinet equipment and the control method thereof can predict the thermal load change of the load device in advance through the output power provided by the power supply device to the load device (i.e., the sensing result of the power sensor), and control the rotation speed of the circulation motor, to adjust the flow of the coolant flowing in the secondary fluid loop pipeline. Therefore, the thermal load is precooled, and the problem that the existing liquid cooling system cannot quickly reach the set thermal equilibrium when the thermal load of the load device suddenly increases due to the slow control response of the liquid medium can be alleviated. In addition, by periodically transmitting the power load information through the power sensor 136, and the design of the threshold, it can avoid the problem of damage to the circulation motor 135 caused by excessive control of the circulation motor 135 due to factors such as sensing errors of the output power. Moreover, by the arrangement of the liquid temperature sensor and/or the load temperature sensor, the liquid cooling system can maintain normal operation when the power sensor is damaged.

Although the above-described components are depicted in the drawings of the present disclosure, it cannot be excluded that more other additional elements may be used to achieve better technical effects without departing from the spirit of the present disclosure. Although the present disclosure is described with the above embodiments, it should be noted that these descriptions are not intended to limit the present disclosure. It will be apparent to those skilled in the art that various modifications and variations can be made without departing from the spirit of the present disclosure.

What is claimed is:

1. A liquid cooling cabinet equipment, comprising:
a load device;
a power supply device configured to supply power to the load device; and
a liquid cooling system, comprising:
a liquid storage tank configured to store a coolant;
a primary fluid loop pipeline connected to an external cooling device;
a secondary fluid loop pipeline communicating with the liquid storage tank and being in thermal contact with the load device;
a heat exchanger, a primary side of the heat exchanger communicating with the primary fluid loop pipeline, and a secondary side of the heat exchanger communicating with the secondary fluid loop pipeline;
a circulation motor configured to drive the coolant in the liquid storage tank to circulate in the secondary fluid loop pipeline, wherein after exchanging heat with the load device, the coolant in the secondary fluid loop pipeline exchanges heat with another coolant in the primary fluid loop pipeline through the heat exchanger;
a power sensor configured to sense an output power provided by the power supply device to the load device; and
a control device connected to the circulation motor, and configured to receive power load information from the power sensor, and control a rotation speed of the circulation motor based on the power load information to adjust a flow of the coolant in the secondary fluid loop pipeline, wherein the power load information comprises the output power.

2. The liquid cooling cabinet equipment according to claim 1, wherein the control device is further configured to control the rotation speed of the circulation motor based on the power load information and a look-up table.

3. The liquid cooling cabinet equipment according to claim 1, wherein the control device is further configured to control the rotation speed of the circulation motor based on the power load information, and a rotation speed upper limit value and a rotation speed lower limit value of the circulation motor.

4. The liquid cooling cabinet equipment according to claim 1, wherein the number of the load devices is plural, the load devices are arranged in parallel through the secondary fluid loop pipeline, the power supply device supplies power to the load devices, the power sensor is further configured to sense a total output power provided by the power supply device to the load devices, and the power load information comprises the total output power.

5. The liquid cooling cabinet equipment according to claim 4, wherein the power supply device comprises a plurality of power supply units, the number of the circulation motors is plural; the power supply units, the circulation motors and the loads devices are arranged in one-to-one correspondence, each power supply unit is configured to supply power to the corresponding load device, and each circulation motor is configured to drive the flow of the coolant for heat exchange with the corresponding load device.

6. The liquid cooling cabinet equipment according to claim 5, wherein the power sensor is further configured to sense an output power provided by each power supply unit to the corresponding load device, the power load information comprises the output power provided by each power supply unit to the corresponding load device, and the control device controls a rotation speed of each circulation motor based on the power load information to adjust a flow of the coolant flowing through the corresponding load device.

7. The liquid cooling cabinet equipment according to claim 4, wherein the liquid cooling system further comprises a plurality of flow control valves, the power supply device comprises a plurality of power supply units; the plurality of power supply units, the plurality of flow control valves, and the load devices are arranged in one-to-one correspondence, the power sensor is further configured to sense an output power provided by each power supply unit to the corresponding load device, the power supply load information further comprises the output power provided by each power supply unit to the corresponding load device, and the control device is further configured to control each flow control valve and the circulation motor based on the power load information to adjust a flow of the coolant flowing through each corresponding load device.

8. The liquid cooling cabinet equipment according to claim 1, wherein, the power sensor transmits the power load information to the control device through a wired transmission interface and/or a wireless transmission interface.

9. The liquid cooling cabinet equipment according to claim 1, wherein the power sensor is integrated into the power supply device.

10. The liquid cooling cabinet equipment according to claim 1, wherein the power sensor is further configured to periodically transmit the power load information to the control device, and the control device is further configured to determine whether a variation of the output power is greater than a threshold; when the control device determines that the variation of the output power is greater than the threshold, the control device performs calculation based on the variation of the output power to obtain a flow compensation value, and controls the rotation speed of the circulation motor based on the flow compensation value.

11. The liquid cooling cabinet equipment according to claim 1, wherein the power sensor is configured to obtain the output power based on a supply voltage and/or a supply current provided by the power supply device to the load device.

12. The liquid cooling cabinet equipment according to claim 1, wherein the liquid cooling system further comprises a liquid temperature sensor, and the liquid temperature sensor is configured to sense a temperature of the coolant flowing into the heat exchanger in the secondary fluid loop pipeline to output liquid temperature information to the control device, so that the control device controls the rotation speed of the circulation motor based on the power load information and the liquid temperature information.

13. The liquid cooling cabinet equipment according to claim 1, wherein the liquid cooling system further comprises a load temperature sensor, and the load temperature sensor is configured to sense a temperature of the load device to output load temperature information to the control device, so that the control device controls the rotation speed of the circulation motor based on the power load information and the load temperature information.

14. The liquid cooling cabinet equipment according to claim 1, further comprising a cabinet body, wherein the load device, the power supply device and the liquid cooling system are integrated into an interior of the cabinet body.

15. A control method of a liquid cooling cabinet equipment, which is applied to the liquid cooling cabinet equipment comprising a load device, a power supply device for supplying power to the load device, a liquid storage tank, a primary fluid loop pipeline connected to an external cooling device, a secondary fluid loop pipeline communicating with the liquid storage tank and in thermal contact with the load device, a heat exchanger and a circulation motor, the control method of the liquid cooling cabinet equipment comprising the following steps:
(a) controlling the circulation motor to drive a coolant in the liquid storage tank to circulate in the secondary fluid loop pipeline, so that after exchanging heat with the load device, the coolant in the secondary fluid loop pipeline exchanging heat with another coolant in the primary fluid loop pipeline through the heat exchanger;
(b) sensing an output power provided by the power supply device to the load device, and outputting power load information, the power load information comprising the output power; and
(c) controlling a rotation speed of the circulation motor based on the power load information to adjust a flow of the coolant flowing in the secondary fluid loop pipeline.

16. The control method of the liquid cooling cabinet equipment according to claim 15, wherein step (c) comprises:
controlling the rotational speed of the circulation motor based on the output power and a look-up table.

17. The control method of the liquid cooling cabinet equipment according to claim 15, wherein step (c) comprises:
controlling the rotation speed of the circulation motor based on the output power and a rotation speed upper limit value and a rotation speed lower limit value of the circulation motor.

18. The control method of the liquid cooling cabinet equipment according to claim 15, wherein the number of the circulating motors is plural, the number of the load devices is plural, the load devices are arranged in parallel through the secondary fluid loop pipeline, the power supply device comprises a plurality of power supply units; the plurality of power supply units, the circulation motors and the load devices are arranged in one-to-one correspondence; step (b) comprises: sensing an output power provided by each power supply unit to the corresponding load device, and outputting the power load information, the power load information comprising the output power provided by each power supply unit to the corresponding load device; and step (c) comprises: controlling a rotation speed of each circulation motor based on the output power provided by each power supply unit to the corresponding load device to adjust a flow of the coolant flowing through the corresponding load device.

19. The control method of the liquid cooling cabinet equipment according to claim 15, wherein step (b) comprises: periodically sensing the output power, and step (c) comprises: determining whether a variation of the output power is greater than a threshold; and when it is determined that the variation of the output power is greater than the threshold, performing calculation based on the variation of the output power to obtain a flow compensation value, and controlling the rotation speed of the circulation motor based on the flow compensation value.

20. The control method of the liquid cooling cabinet equipment according to claim 15, wherein the number of the load devices is plural, the load devices are arranged in parallel through the secondary fluid loop pipeline, and the power supply device supplies power to the load devices, step (b) comprises: sensing a total output power provided by the power supply device to the load devices, and outputting the power load information, the power load information comprising the total output power, and step (c) comprises: controlling the rotation speed of the circulation motor based on the total output power to adjust the flow of the coolant flowing in the secondary fluid loop pipeline.
